(19) United States
(12) Patent Application Publication
(10) Pub. No.: US 2026/0013225 A1
(43) Pub. Date: Jan. 8, 2026

(54) DISPLAY PANEL AND DISPLAY DEVICE

(71) Applicant: Wuhan Tianma Micro-Electronics Co., Ltd., Wuhan (CN)

(72) Inventor: Pan TIAN, Wuhan (CN)

(21) Appl. No.: 19/010,749

(22) Filed: Jan. 6, 2025

(30) Foreign Application Priority Data
Jul. 8, 2024 (CN) 202410911344.1

(51) Int. Cl. H10D 86/40

(52) U.S. Cl. CPC H10D 86/421; H10D 86/441

(57) ABSTRACT

A display panel and a display device are provided. The display panel includes a substrate and an array layer. The array layer includes at least one thin film transistor. One thin film transistor includes an active layer, a gate, a source, and a drain. The active layer is located on the substrate, and includes a concave structure. The concave structure includes a bottom surface and a side surface. The gate is located on a side of the active layer away from the substrate. Along a direction perpendicular to the side surface of the concave structure, at least part of the gate overlaps with the side surface of the concave structure. The array layer includes a floating metal layer between the active layer and the substrate, which is in direct contact with at least part of the side surface of the concave structure.

### CROSS-REFERENCE TO RELATED APPLICATION

This application claims the priority of Chinese Patent Application No. 202410911344.1, filed on Jul. 8, 2024, the content of which is incorporated herein by reference in its entirety.

### TECHNICAL FIELD

The present disclosure generally relates to the field of display technology and, more particularly, relates to a display panel and a display device.

### BACKGROUND

With the continuous development of science and technology, more and more display products, such as mobile phones, tablet computers, laptops, and smart wearable devices, are widely used in people's daily life and work, bringing great convenience to people's daily life and work, and becoming an indispensable tool for people today.

A main component of a display product to realize a display function is a display panel. An array layer in the display panel is provided with thin film transistor (TFT) devices. Because of structural limitations of a TFT device itself, the TFT device occupies a large area in the display panel, resulting in limited improvement in the PPI (Pixels per inch, pixel density) of the display product.

### SUMMARY

One aspect of the present disclosure provides a display panel. The display panel includes a substrate and an array layer on a side of the substrate. The array layer includes at least one thin film transistor. One thin film transistor includes an active layer, a gate, a source, and a drain. The active layer is located on one side of the substrate, and includes a concave structure formed along a first direction. The concave structure includes a bottom surface and a side surface. The gate is located on a side of the active layer away from the substrate. Along a direction perpendicular to the plane where the side surface of the concave structure is located, at least part of the gate overlaps with the side surface of the concave structure. The array layer includes a floating metal layer located between the active layer and the substrate. The floating metal layer is in direct contact with at least part of the side surface of the concave structure. The first direction is perpendicular to the substrate and is from the floating metal layer to the substrate.

Another aspect of the present disclosure provides a display device. The display device includes a display panel. The display panel includes a substrate and an array layer on a side of the substrate. The array layer includes at least one thin film transistor. One thin film transistor includes an active layer, a gate, a source, and a drain. The active layer is located on one side of the substrate, and includes a concave structure formed along a first direction. The concave structure includes a bottom surface and a side surface. The gate is located on a side of the active layer away from the substrate. Along a direction perpendicular to the plane where the side surface of the concave structure is located, at least part of the gate overlaps with the side surface of the concave structure. The array layer includes a floating metal layer located between the active layer and the substrate. The floating metal layer is in direct contact with at least part of the side surface of the concave structure. The first direction is perpendicular to the substrate and is from the floating metal layer to the substrate.

Other aspects or embodiments of the present disclosure can be understood by those skilled in the art in light of the description, the claims, and the drawings of the present disclosure.

### BRIEF DESCRIPTION OF THE DRAWINGS

The following drawings are merely examples for illustrative purposes according to various disclosed embodiments and are not intended to limit the scope of the present disclosure.

FIG. 1 illustrates a TFT device.

FIG. 2 illustrates a planar structure of an exemplary display panel consistent with various disclosed embodiments in the present disclosure.

FIG. 3 illustrates a planar structure of a thin film transistor in an exemplary display panel consistent with various disclosed embodiments in the present disclosure.

FIG. 4 illustrates a cross-sectional view of the thin film transistor in FIG. 3, along an AA direction, consistent with various disclosed embodiments in the present disclosure.

FIG. 5 illustrates a cross-sectional view of an active layer in the thin film transistor in FIG. 3 along the AA direction consistent with various disclosed embodiments in the present disclosure.

FIG. 6 illustrates another cross-sectional view of the thin film transistor in FIG. 3, along an AA direction, consistent with various disclosed embodiments in the present disclosure.

FIG. 7 illustrates another cross-sectional view of the thin film transistor in FIG. 3, along an AA direction, consistent with various disclosed embodiments in the present disclosure.

FIG. 8 illustrates a position relationship between a floating metal layer and grooves consistent with various disclosed embodiments in the present disclosure.

FIG. 9 illustrates a position relationship between side surfaces of a floating metal layer and a concaved structure consistent with various disclosed embodiments in the present disclosure.

FIG. 10 illustrates another position relationship between a floating metal layer and grooves consistent with various disclosed embodiments in the present disclosure.

FIG. 11 illustrates another position relationship between side surfaces of a floating metal layer and a concaved structure consistent with various disclosed embodiments in the present disclosure.

FIG. 12 illustrates another planar structure of a thin film transistor in an exemplary display panel consistent with various disclosed embodiments in the present disclosure.

FIG. 13 illustrates a cross-sectional view of the thin film transistor in FIG. 12 along a BB direction consistent with various disclosed embodiments in the present disclosure.

FIG. 14 illustrates another planar structure of a thin film transistor in an exemplary display panel consistent with various disclosed embodiments in the present disclosure.

FIG. 15 illustrates another planar structure of a thin film transistor in an exemplary display panel consistent with various disclosed embodiments in the present disclosure.

FIG. 16 illustrates another planar structure of a thin film transistor in an exemplary display panel consistent with various disclosed embodiments in the present disclosure.

FIG. 17 illustrates another planar structure of a thin film transistor in an exemplary display panel consistent with various disclosed embodiments in the present disclosure.

FIG. 18 illustrates another planar structure of a thin film transistor in an exemplary display panel consistent with various disclosed embodiments in the present disclosure.

FIG. 19 illustrates a film layer structure of an exemplary thin film transistor consistent with various disclosed embodiments in the present disclosure.

FIG. 20 illustrates an electronic device corresponding to the thin film transistor in FIG. 19, consistent with various disclosed embodiments in the present disclosure.

FIG. 21 illustrates an exemplary display device consistent with various disclosed embodiments in the present disclosure.

### DETAILED DESCRIPTION

Reference will now be made in detail to exemplary embodiments of the disclosure, which are illustrated in the accompanying drawings. Hereinafter, embodiments consistent with the disclosure will be described with reference to drawings. In the drawings, the shape and size may be exaggerated, distorted, or simplified for clarity. Wherever possible, the same reference numbers will be used throughout the drawings to refer to the same or like parts, and a detailed description thereof may be omitted.

Further, in the present disclosure, the disclosed embodiments and the features of the disclosed embodiments may be combined under conditions without conflicts. It is apparent that the described embodiments are some but not all of the embodiments of the present disclosure. Based on the disclosed embodiments, persons of ordinary skill in the art may derive other embodiments consistent with the present disclosure, all of which are within the scope of the present disclosure.

Moreover, the present disclosure is described with reference to schematic diagrams. For the convenience of descriptions of the embodiments, the cross-sectional views illustrating the device structures may not follow the common proportion and may be partially exaggerated. Besides, those schematic diagrams are merely examples, and not intended to limit the scope of the disclosure. Furthermore, a three-dimensional (3D) size including length, width, and depth should be considered during practical fabrication.

In the present disclosure, relational terms such as first and second are only used to distinguish one entity or operation from another entity or operation, and do not necessarily require or imply any such actual relationship between these entities or operations or order. Moreover, the terms “including”, “comprising” or any other variants thereof are intended to cover non-exclusive inclusion, such that a process, method, article, or device that includes a series of elements includes not only those elements, but also those that are not explicitly listed or also include elements inherent to this process, method, article or equipment. If there are no more restrictions, the elements defined by the sentence “including . . . ” do not exclude the existence of other same elements in the process, method, article, or equipment that includes the elements.

It should be understood that when describing the structure of a component, when a layer or region is referred to as being “on” or “above” another layer or another region, the layer or region may be directly on the other layer or region, or indirectly on the other layer or region, for example, layers/components between the layer or region and another layer or another region. And, for example, when the component is reversed, the layer or region may be “below” or “under” the other layer or region. In the present disclosure, the term “electrical connection” refers to that two components are directly electrically connected with each other, or the two components are electrically connected via one or more other components.

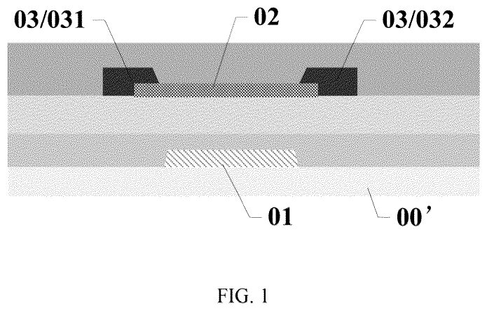

FIG. 1 illustrates an exemplary thin film transistor device in existing technologies. As shown in FIG. 1, the TFT device generally includes a gate 01, an active layer 02 and a source-drain layer 03, arranged on a substrate 00′ in sequence. The source-drain layer 03 includes a source 031 and a drain 032 respectively connected to the active layer 02 and arranged at intervals. A portion of the active layer 02 overlapping with the gate 01 is a channel of the TFT device. The TFT device with this structure occupies a relatively large area in display products, which is not conducive to improving the resolution of the product (Pixels Per Inch, PPI). Further, the driving ability of the TFT device is positively correlated with the width-to-length ratio of the channel. By reducing the length of the channel of the TFT device, its driving ability may be improved and the area occupied by the device may be reduced to a certain extent. However, when the channel length of the TFT device is set too small, excessive accumulation of electrons in the channel of the TFT device will appear, causing the TFT device to heat up or even burn. Therefore, how to reduce the area occupied by the TFT device in the display product to improve the PPI, while also avoiding the heating or even burning of the TFT device caused by the short channel length, has become one of the technical problems that needs to be solved at this stage.

The present disclosure provides a display panel and a display device to at least partially alleviate the above problems.

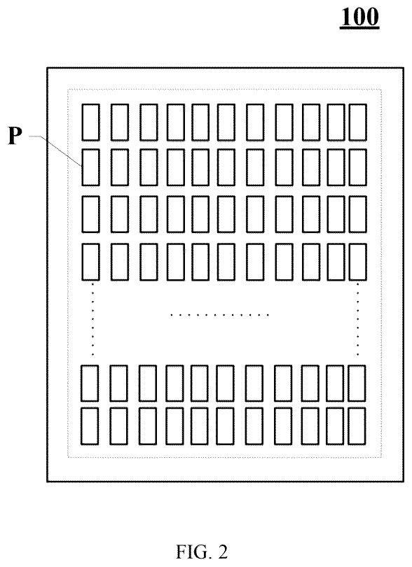

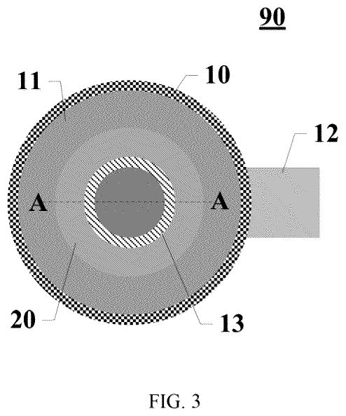

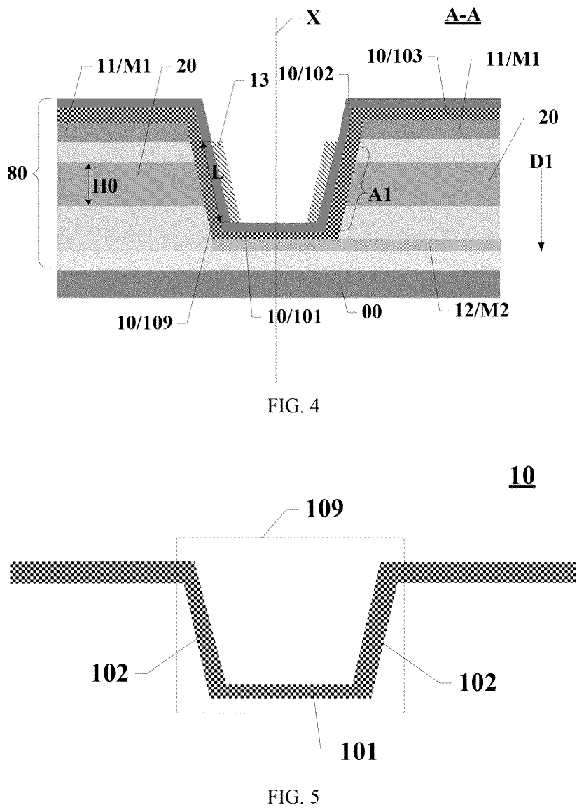

One aspect of the present disclosure provides a display panel. FIG. 2 illustrates a planar structure of an exemplary display panel, FIG. 3 illustrates a planar structure of an exemplary thin film transistor, and FIG. 4 illustrates a cross-sectional view of the thin film transistor in FIG. 3 along an AA direction, consistent with various embodiments of the present disclosure. As shown in FIG. 2 to FIG. 4, in one embodiment, the display panel 100 may include a substrate 00 and an array layer 80 located on one side of the substrate 00. The array layer 80 may include at least one thin film transistor 90. One thin film transistor 90 may include an active layer 10, a gate 13, and a source/drain 11/12. The active layer 10 may be disposed on one side of the substrate 00. The active layer 10 may include a concave structure 109 formed along a first direction D1. The concave structure 109 may include a bottom surface 101 of the concave structure 109 and a side surface 102 of the concave structure 109. The gate 13 may be located on a side of the active layer 10 away from the substrate 00. Along a direction perpendicular to the plane where the side surface 102 of the concave structure 109 is located, at least part of the gate 13 may overlap with the side surface 102 of the concave structure 109. The array layer 80 may include a floating metal layer 20, and the floating metal layer 20 may be located between the active layer 10 and the substrate 00. The floating metal layer 20 may be in direct contact with at least part of the side surface 102 of the concave structure 109. The first direction D1 may be perpendicular to the substrate 00 and from the floating metal layer 20 to the substrate 00.

Compared with the TFT device shown in FIG. 1, in the thin film transistor 90 of the display panel provided by the present disclosure, the active layer 10 may include the concave structure 109 formed along the first direction D1, and the concave structure 109 may be a structure that bends downward in the direction from the floating metal layer 20 to the substrate 00, rather than a planar structure in a conventional TFT device. When the length of the active layer 10 is fixed, a projection of active layer 10 with the form of the concave structure 109 on the plane where the light emitting surface of the display panel is located may occupy a smaller area than the planar structure, which is more conducive to reducing the area occupied by the thin film transistor in the display panel and improving the PPI of the product.

The concave structure 109 of the active layer 10 may include the bottom surface 101 of the concave structure 109 and the side surface 102 of the concave structure 109. The bottom surface 101 of the concave structure 109 may refer to the bottom of the concave structure 109. Generally, the bottom surface 101 of the concave structure 109 may be parallel to or substantially parallel to the surface of the substrate 00. For example, when the angle between the bottom surface 101 of the concave structure 109 and the plane where the substrate 00 is located is less than 5°, the bottom surface 101 of the concave structure 109 and the plane where the substrate 00 is located may be considered to be parallel or substantially parallel. The side surface 102 of the concave structure 109 may be connected to the bottom surface 101 of the concave structure 109 and may be located on the sides of the bottom surface 101 of the concave structure 109 away from the substrate 00. Optionally, the angle between the bottom surface 101 of the concave structure 109 and the side surface 102 of the concave structure 109 may be larger than or equal to 90°. In a direction perpendicular to the plane where the side surface 102 of the concave structure 109 is located, at least part of the gate 13 may overlap with the side surface 102 of the concave structure 109, and the overlapping area may form the channel region or part of the channel region of the thin film transistor. When the channel region is set to a planar structure, along the extension direction of the active layer 10, that is, along the length direction of the channel region, the length of the channel region is only reflected in the length on the planar structure. When the area occupied by the thin film transistor in the display panel is reduced to increase the PPI, the channel length will inevitably decrease, which may be very likely to cause excessive accumulation of electrons in the channel of the thin film transistor device, resulting in heat or even burning. When the present disclosure sets the active layer 10 to include the concave structure 109, at least part of the channel region may be located on a side of the side surface 102 of the concave structure 109 that intersects with the bottom surface 101 of the concave structure 109, and the length of the channel region may be also related to the length of the side surface 102 of the concave structure 109. Therefore, the present disclosure may be conducive to increasing the length of the channel region when setting the thin film transistor in a smaller area. Even when the PPI is increased by reducing the area occupied by the thin film transistor in the display panel, it may still be ensured that the length of the channel region may be not too short.

Further, in the present disclosure, the floating metal layer 20 may be provided in the display panel. In the thin film transistor 90, the floating metal layer 20 may be in direct contact with at least a part of the side surface 102 of the concave structure 109. The channel region of the active layer 10 may be in direct contact with the floating metal layer 20, which may effectively reduce the source-drain voltage difference of the thin film transistor 90, improve the negative bias of the threshold voltage of the thin film transistor 90, and improve the display quality. On the other hand, when the active layer 10 is in direct contact with the floating metal layer 20, when the thin film transistor generates heat, the heat may be conducted to the floating metal layer 20 through the concave structure 109. The floating metal layer 20 may be able to conduct heat to prevent heat from accumulating in the channel region and causing the thin film transistor to heat up or burn, which may be beneficial to improving the stability of the performance of the thin film transistor. Also, the floating metal layer 20 may be in direct contact with at least a part of the side surface 102 of the concave structure 109 in the channel region of the active layer 10, and the floating metal layer 20 in direct contact with the side surface 102 of the concave structure 109 may realize the adjustment of the contact area between the floating metal layer 20 and the concave structure 109 by adjusting the angle of the side of the floating metal layer 20, while ensuring that the length of the channel region is maintained within a reasonable range.

The embodiment shown in FIG. 2 with a rectangular display panel is used as an example only to illustrate the present disclosure, and does not limit the shape of the display panel in various embodiments of the present disclosure. In some other embodiments, the display panel may have any other suitable shape, such as a rounded rectangle or a circle. Also, the embodiment shown in FIG. 2 with an arrangement of sub-pixels P is used as an example only to illustrate the present disclosure, and does not limit the arrangement of the sub-pixels P in the present disclosure. For example, in some embodiments, one or more thin film transistors in the pixel driving circuit corresponding to the sub-pixels may be embodied as the structure in the above embodiment. FIG. 3 only illustrates a top view structure of a thin film transistor in the display panel, and does not represent the actual size. In addition to the circular structure shown in FIG. 3, the thin film transistor may also be in other shapes, which will be explained in the following embodiments. FIG. 4 only illustrates the film layers related to the thin film transistor and the floating metal layer 20 in the display panel, and does not show other film layer structures of the display panel, and does not limit the actual number and size of the film layers of the display panel.

As shown in FIG. 3 and FIG. 4, in one embodiment, the side surface 102 of the concave structure 109 may include a first area A1, and the gate 13 may overlap with the first area A1 along the direction perpendicular to the plane where the side surface 102 of the concave structure 109 is located, and the floating metal layer 20 may be in direct contact with at least a portion of the first area A1.

The floating metal layer 20 and the gate 13 may be disposed on two sides of the side surface 102 of the concave structure 109 corresponding to the active layer 10 respectively. The gate 13 may be arranged inside the concave structure 109, and the floating metal layer 20 may be arranged outside the concave structure 109. That is, the gate 13 may be arranged on the side surface 102 of the concave structure 109 facing the center line X of the concave structure 109. The gate 13 and the side surface 102 of the concave structure 109 may be separated by an insulating layer. The floating metal layer 20 may be arranged on a side of the side surface 102 of the concave structure 109 away from the center line X of the concave structure 109, and the floating metal layer 20 may be in direct contact with the side surface 102 of the concave structure 109. In the direction perpendicular to the plane where the side surface 102 of the concave structure 109 is located, the gate 13 may overlap with the first area A1. The area where the gate 13 overlaps with the first area A1 may be regarded as the channel region or part of the channel region of the thin film transistor. When the floating metal layer 20 is in direct contact with at least part of the first area A1, it may be equivalent to that the floating metal layer 20 may overlap and be in direct contact with the channel region of the thin film transistor in the direction perpendicular to the plane where the side surface 102 of the concave structure 109 is located. Therefore, the source-drain voltage difference of the thin film transistor 90 may be effectively reduced, the negative bias of the threshold voltage of the thin film transistor 90 may be improved, and the display quality may be improved. Moreover, when heat is generated in the channel region, the floating metal layer 20 may be able to conduct the heat in the first time, which is conducive to further avoiding the accumulation of heat in the channel region and causing the thin film transistor to heat up or burn, thereby helping to improve the stability of the performance of the thin film transistor.

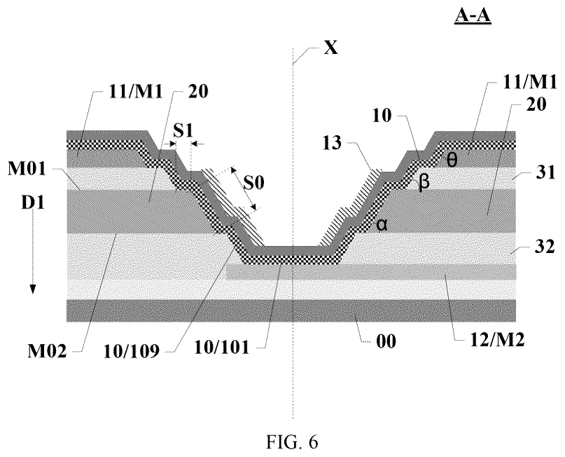

As shown in FIG. 6 which is a cross-sectional view of the thin film transistor in FIG. 3 along the AA direction, in one embodiment, a surface of the floating metal layer 20 facing away from the substrate 00 may be the first surface M01. The floating metal layer 20 may face the side surface 102 of the concave structure 109, and at least part of the first surface M01 may be in contact with the side surface 102 of the concave M-shaped structure.

In the embodiment shown in FIG. 6, in addition to the side surface of the floating metal layer 20 being in contact with the side surface 102 of the concave structure 109, at least part of the first surface M01 of the floating metal layer 20 may be also in contact with the side surface 102 of the concave structure 109. This arrangement may be equivalent to increasing the contact area between the floating metal layer 20 and the side surface 102 of the concave structure 109. When the contact area between the floating metal layer 20 and the side surface 102 of the concave structure 109 is larger, the source-drain voltage difference of the thin film transistor may be reduced further, to improve the negative bias problem of the threshold voltage of the thin film transistor. Moreover, when the contact area between the floating metal layer 20 and the side 102 of the concave structure 109 is larger, the thermal conductivity of the floating metal layer 20 may be better. When heat is generated in the channel region of the thin film transistor, the heat may be dissipated promptly through the side surface and the first surface of the floating metal layer 20, which is beneficial to reduce the heat conduction time and improve the heat conduction efficiency, thereby being more beneficial to avoid heating or burning caused by heat accumulation in the thin film transistor.

As shown in FIG. 6, in one embodiment, along the extension direction of the active layer 10, the contact width between the active layer 10 and the first surface of the floating metal layer 20 located on one side of the concave structure 109 may be S1, the contact width between the active layer 10 and the side wall of the floating metal layer 20 located on one side of the concave structure 109 may be SO, and the sum of the contact widths between the active layer 10 and the first surface of the floating metal layer 20 located on two sides of the concave structure 109 may be S2, where S1<S0, S0/2<S2.

The extension direction of the active layer 10 may be regarded as the direction extending from the bottom surface 101 of the concave structure 109 to the side surface 102 of the concave structure 109. When the contact width between the first surface M01 of the floating metal layer 20 and the active layer 10 is larger, the area occupied by the thin film transistor in the display panel may be larger, which is less conducive to the improvement of the PPI of the display panel. In the present disclosure, the contact width S1 between the first surface M01 of the floating metal layer 20 located on one side of the concave structure 109 and the active layer 10 may be set to be smaller than the contact width SO between the side wall of the floating metal layer 20 and the active layer 10, and the total width S2 of the first surface M01 of the floating metal layer 20 located on two sides of the concave structure 109 may be set to be larger than S0/2 at the same time. In this way, it may be beneficial to increase the contact area between the floating metal layer 20 and the active layer 10 and improve the heat dissipation efficiency of the floating metal layer 20. Also, the contact area between the first surface M01 and the active layer 10 may be prevented from being too large and causing the thin film transistor to occupy a large area in the display panel. The heat dissipation efficiency may be ensured while improving the PPI.

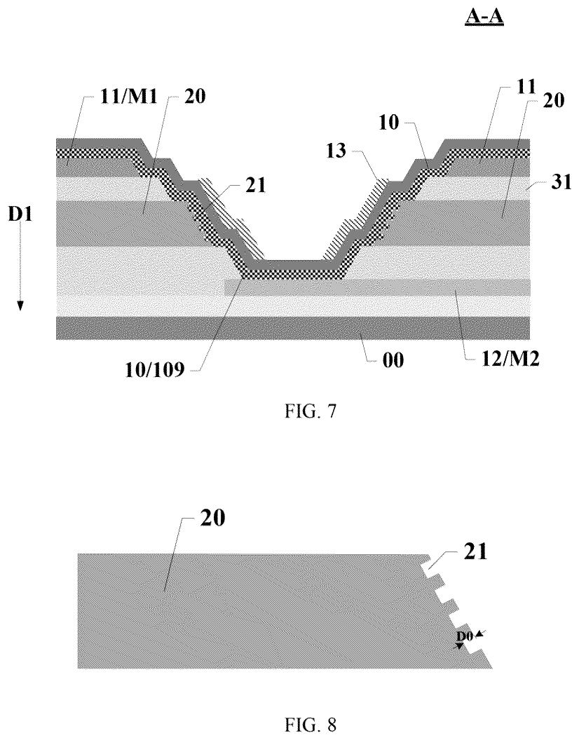

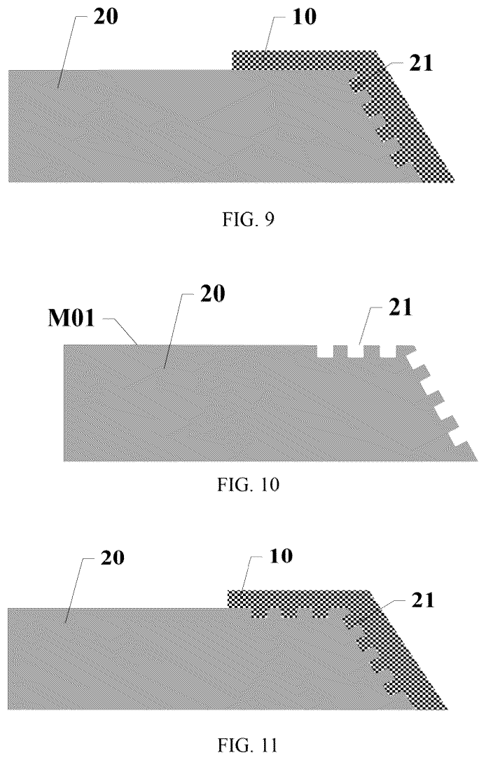

FIG. 7 shows another cross-sectional view of the thin film transistor along the AA direction in FIG. 3, FIG. 8 shows a relative position relationship diagram between the floating metal layer 20 and the grooves 21, and FIG. 9 shows a relative position relationship diagram between the floating metal layer 20 and the side surface 102 of the concave structure 109. As shown in FIG. 7 to FIG. 9, in one embodiment, the side wall of the floating metal layer 20 facing the concave structure 109 may include grooves 21.

In the present embodiment, the sidewall of the floating metal layer 20 in contact with the side surface 102 of the concave structure 109 may be provided with the grooves 21, and the grooves 21 may be regarded as structures that are recessed along the sidewall of the floating metal layer 20 toward the inside of the floating metal layer 20. In the actual process, the floating metal layer 20 with the concave structure 109 may be first formed before the active layer 10 is further formed. The active layer 10 may be usually formed by deposition. Therefore, during the deposition process, at least part of the active layer 10 may be filled into the groove 21 of the floating metal layer 20. Compared with the planar structure, the form of providing the groove 21 may increase the contact area between the floating metal layer 20 and the active layer 10, which is beneficial to improving the heat dissipation effect of the floating metal layer 20, reducing the source-drain voltage difference of the thin film transistor, and improving the negative bias problem of the threshold voltage of the thin film transistor.

As shown in FIG. 7 and FIG. 9, in one embodiment, the depth of the grooves 21 may be D0, where 0.2 μm≤D0≤0.5 μm. The depth of the grooves 21 may be regarded as the height from the notches of the grooves 21 to the bottoms of the grooves 21. When the depth of the grooves 21 is too small, for example, less than 0.2 μm, the improvement effect on the contact area between the floating metal layer 20 and the active layer 10 may be not enough. When the depth of the grooves 21 is too large, for example, larger than 0.5 μm, the difficulty of the groove manufacturing process may be increased. Therefore, in the present disclosure, the depth of the grooves 21 may be set to 0.2 μm≤D0≤0.5 μm, which may effectively increase the contact area between the floating metal layer 20 and the active layer 10, improve the heat dissipation effect of the floating metal layer 20 on the active layer 10, and avoid increasing the difficulty of the manufacturing process. At the same time, when depositing the active layer 10, the above-mentioned setting method of the depth of the grooves 21 may be also conducive to ensuring that the active layer 10 has good coverage of the side wall of the floating metal layer 20. It should be noted that the structure of the grooves 21 in the drawings of the present disclosure is only for illustration, and the actual shapes and numbers of the grooves 21 are not limited. In actual production, the grooves 21 may be embodied as a dot structure arranged in an array on the side wall of the floating metal layer 20, or as a long strip structure, or as a ring structure, and the present disclosure does not specifically limit this. The shape of the orthographic projection of one groove 21 on the side wall of the floating metal layer 20 may be square, circular, triangular or ring-shaped, etc., and the present disclosure does not specifically limit this.

FIG. 10 shows another relative position relationship diagram of the floating metal layer 20 and the grooves 21, and FIG. 11 shows another relative position relationship diagram of the floating metal layer 20 and the side surface 102 of the concave structure 109. As shown in FIG. 10 and FIG. 11, in one embodiment, the first surface M01 of the floating metal layer 20 in contact with the active layer 10 may include the grooves 21.

In this embodiment, the side wall and the first surface M01 of the floating metal layer 20 in contact with the active layer 10 may both be provided with the grooves 21. The size and shape of the grooves 21 provided on the first surface M01 of the floating metal layer 20 may refer to the grooves 21 provided on the side wall of the floating metal layer 20, which may be manufactured in the same process. In this embodiment, when grooves 21 are set on the side wall and the first surface M01 of the floating metal layer 20, the contact area between the floating metal layer 20 and the active layer 10 may be further increased, which is more conducive to improving the heat dissipation effect of the floating metal layer 20 on the active layer 10, and is beneficial to reducing the source-drain voltage difference of the thin film transistor and improving the negative bias problem of the threshold voltage of the thin film transistor.

In one embodiment shown in FIG. 6, a surface of the floating metal layer 20 facing the substrate 00 may be the second surface M02, and the angle between the side wall of the floating metal layer 20 facing the concave structure 109 and the second surface M02 may be α, where 60°≤α≤80°.

In this embodiment, the side wall of the floating metal layer 20 facing the concave structure 109 may be set to be inclined, and the angle between the side wall of the floating metal layer 20 facing the concave structure 109 and its second surface M02 may be an acute angle. When the above-mentioned angle α is too small, for example, less than 60°, to achieve the same thickness of the floating metal layer 20, the area occupied by the floating metal layer 20 in the display panel may be larger, and the area occupied by the thin film transistor may also increase, which is not conducive to improving the PPI of the display panel. When the above-mentioned angle α is too large, for example, greater than 80°, the slope of the side wall of the floating metal layer 20 may be steeper, which is not conducive to the adhesion of the subsequently deposited active layer 10, and affects the reliability of the thin film transistor. Therefore, when the thickness of the floating metal layer 20 is constant, the present embodiment may set the angle between the side wall of the floating metal layer 20 in contact with the active layer 10 and the second surface M02 of the floating metal layer 20 to be greater than or equal to 60°, which is beneficial to reducing the area occupied by the floating metal layer 20 in the display panel, thereby reducing the area occupied by the thin film transistor in the display panel, and further beneficial to improving the PPI of the display panel. At the same time, the above-mentioned angle may be set to be less than or equal to 80°, and the slope of the side wall of the floating metal layer 20 may be gentle, which is beneficial to the attachment of the active layer 10 to the side wall of the floating metal layer 20 and improving the coverage reliability of the active layer 10 on the side wall of the floating metal layer 20. Optionally, 65°≤α≤75°, or 70°≤α≤78°, etc.

In one embodiment, as shown in FIG. 4, along the first direction D1, the thickness of the floating metal layer 20 may be H0, where L/3≤H0≤L/2. The area where the gate 13 overlaps with the active layer 10 may be the channel region of the thin film transistor, where L is the length of the channel region on the single side of the concave structure 109, and the length direction of the channel region may be the direction from the side surface 102 of the concave structure 109 and the bottom 101 of the concave structure 109 to the mouth.

When the area occupied by the thin film transistor in the display panel is fixed, the size of the contact area between the side wall of the floating metal layer 20 and the active layer 10 may be related to the thickness of the floating metal layer 20. When the thickness of the floating metal layer 20 is larger, the contact area between the side wall of the floating metal layer 20 and the active layer 10 may be larger, which is more conducive to heat dissipation. Conversely, when the thickness of the floating metal layer 20 is smaller, the contact area between the side wall of the floating metal layer 20 and the active layer 10 may be smaller. When the thickness of the floating metal layer 20 is too small, for example, less than L/3, the contact area between the side wall of the floating metal layer 20 and the active layer 10 may be small, which is not conducive to heat dissipation. When the thickness of the floating metal layer 20 is too large, for example, greater than L/2, the difficulty of the etching process of the floating metal layer 20 may increase, affecting the production efficiency of the display panel. Therefore, when the thickness of the floating metal layer 20 is set to L/3≤H0≤L/2 in the present embodiment, the contact area between the floating metal layer 20 and the active layer 10 may be increased, improving the heat dissipation efficiency of the floating metal layer 20, helping reduce the source-drain voltage difference of the thin film transistor, improving the negative bias problem of the threshold voltage of the thin film transistor, and avoiding the problem of increased difficulty in the etching process when the floating metal layer 20 is too thick to improve the production efficiency of the display panel. Optionally, L=2 μm, and the thickness range of the floating metal layer 20 may be 0.67˜1 μm.

In one embodiment as shown in FIG. 3, the floating metal layer 20 may be an annular closed structure arranged around the concave structure 109.

In this embodiment, the orthographic projection of the concave structure 109 of the active layer 10 on the plane where the substrate 00 is located may be a circle, and its three-dimensional structure may be regarded as a hollow columnar structure. Optionally, the orthographic projection of the gate 13 on the plane where the substrate 00 is located may be an annular structure overlapping with the concave structure 109. At this time, the channel region formed by the overlap of the gate 13 and the concave structure 109 may also be an annular structure. In this embodiment, when the floating metal layer 20 is arranged as an annular closed structure arranged around the concave structure 109, the overlapping area between the floating metal layer 20 and the channel region may be increased. When any area of the channel region generates heat, the corresponding floating metal layer 20 may be able to dissipate the heat, which is more conducive to improving the heat dissipation efficiency of the channel region of the thin film transistor. Further, it may be also more conducive to reducing the source-drain voltage difference of the thin film transistor and improving the negative bias problem of the threshold voltage of the thin film transistor. It should be noted that, the annular closed structure, in addition to the circular ring shape shown in FIG. 3, in another embodiment, may also be a block shape with a hollow in the middle. For example, there may be a hollow in a rectangle, and the hollow may just correspond to the concave structure 109.

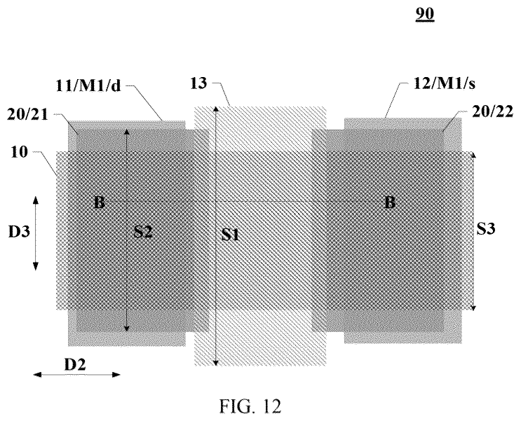

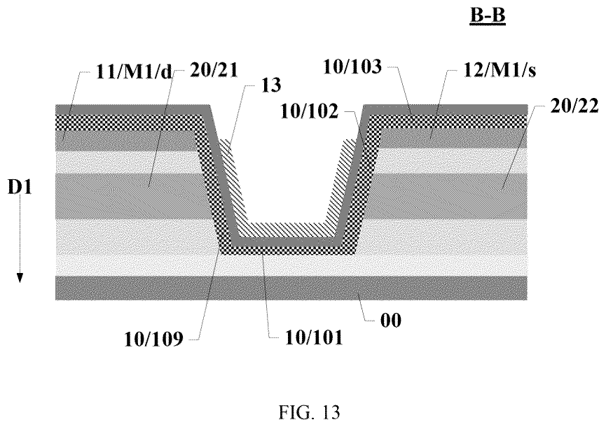

In some other embodiments, the top-view structure of the thin film transistor may also be embodied as a non-annular structure. For example, as shown in FIG. 12 which is another planar structure diagram of a thin film transistor in the display panel provided by the present disclosure and FIG. 13 which is a cross-sectional view of the thin film transistor in FIG. 12 along the BB direction, in one embodiment, the orthographic projection of the active layer 10 on the plane where the substrate 00 is located may be a rectangle, and the concave structure 109 may be regarded as a structure obtained by bending the middle part of the rectangular active layer downward. The source and drain 11 of the thin film transistor may be respectively embodied as rectangular structures overlapping with the active layer 10, and there may be a gap between the source s and the drain d. The orthographic projection of the gate 13 on the plane where the substrate 00 is located may be in the gap between the orthographic projections of the source s and the drain d on the plane where the substrate 00 is located, and may be embodied as a rectangular structure.

As shown in FIG. 12 and FIG. 13, in one embodiment, the floating metal layer 20 may include a first floating metal portion 21 and a second floating metal portion 22 arranged relatively to each other along a second direction D2, and the first floating metal portion 21 and the second floating metal portion 22 may be respectively in contact with two opposite side surfaces of the same concave structure 109. The second direction D2 may be parallel to the plane where the substrate 00 is located, and parallel to the extension direction of the active layer 10 in the bottom surface 101 of the concave structure 109.

In this embodiment, one thin film transistor may correspond to two floating metal portions, namely the first floating metal portion 21 and the second floating metal portion 22. The first floating metal portion 21 and the second floating metal portion 22 may be both located in the floating metal layer 20 and made of the same material and the same process. Optionally, the first floating metal portion 21 and the second floating metal portion 22 may be respectively arranged on the outside of the concave structure 109, for example, arranged on the two opposite side surfaces of the concave structure 109 along the second direction D2, and respectively in contact with the two side surfaces 102 of the concave structure 109. The gate 13 may be arranged inside the concave structure 109. In this embodiment, the gate 13 may be disposed on the side of the bottom surface 101 of the concave structure 109 away from the substrate 00 and the side surface 102 of the concave structure 109 facing the center line of the concave structure 109. The gate 13 may be isolated from the side surface 102 and the bottom surface of the concave structure 109 by an insulating layer, and the area where the gate 13 overlaps with the bottom surface 101 and the side surface of the concave structure 109 may constitute the channel region of the thin film transistor. Along the direction perpendicular to the side surface 102 of the concave structure 109, the first floating metal portion 21 and the second floating metal portion 22 may overlap with the gate 13 respectively, that is, the first floating metal portion 21 and the second floating metal portion 22 may overlap with the channel region of the thin film transistor respectively. When heat is generated in the channel region, the heat may be conducted to the outside of the thin film transistor through the floating metal portions in contact with the concave structure 109, thereby avoiding the problem of heat accumulation inside the thin film transistor. At the same time, the way in which the first floating metal portion 21 and the second floating metal portion 22 overlap and contact with the channel region of the thin film transistor respectively may be also beneficial to reducing the source-drain voltage difference of the thin film transistor, improving the negative bias problem of the threshold voltage of the thin film transistor, and improving the display quality.

In one embodiment shown in FIG. 12, along the third direction D3, the width of the gate 13 may be S1, the width of the floating metal layer 20 may be S2, and the width of the active layer 10 may be S3, wherein S1>S2>S3. The third direction D3 may be parallel to the light emitting surface of the display panel and perpendicular to the second direction D2.

When the orthographic projection of the thin film transistor on the substrate 00 is a non-annular structure as shown in FIG. 12, the width S1 of the gate 13 along the third direction D3 may be set to be larger, such that S1 is larger than the width S2 of the floating metal layer 20 along the third direction D3 and the width S3 of the active layer 10 along the third direction D3. The width of the gate 13 which is larger may be more conductive to controlling the opening and closing of the channel of the thin film transistor. At the same time, in this embodiment, the width S2 of the floating metal layer 20 along the third direction D3 may be set to be greater than the width S3 of the active layer 10 along the third direction D3, which is beneficial to increasing the contact area between the floating metal layer 20 and the active layer 10, and increasing the thermal conductivity area of the floating metal layer 20 by increasing the width of the floating metal layer 20. Therefore, the heat dissipation efficiency of the thin film transistor may be improved, and at the same time the source-drain voltage difference of the thin film transistor may be reduced and the negative bias problem of the threshold voltage of the thin film transistor may be improved.

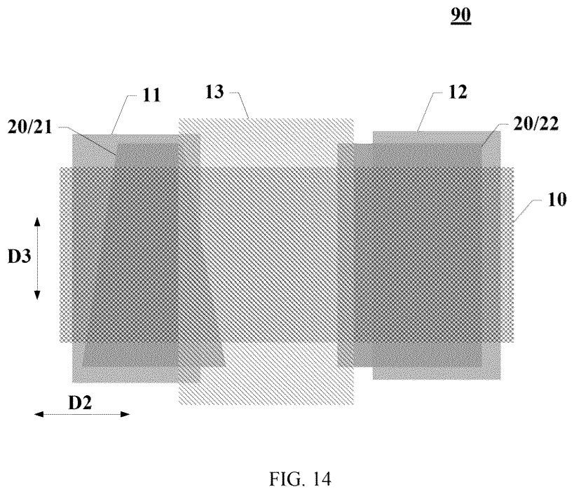

As shown in FIG. 12, when the first floating metal portion 21 and the second floating metal portion 22 corresponding to the same thin film transistor are introduced into the display panel, the first floating metal portion 21 and the second floating metal portion 22 may be symmetrically arranged on two sides of the concave structure 109. In some other embodiments of the present disclosure, the first metal portion M11 and the second metal portion M12 may also be set to an asymmetric structure. For example, as shown in FIG. 14 which is another planar structure diagram of a thin film transistor in the display panel provided by the present disclosure, the first floating metal portion 21 and the second floating metal portion 22 may be embodied as an asymmetric structure.

As shown in FIG. 14, in one embodiment, the width of the first floating metal portion 21 along the second direction D2 may be different from the width of the second floating metal portion 22 along the second direction D2. In this embodiment, the shapes of the orthographic projections of the first floating metal portion 21 and the second floating metal portion 22 on the plane where the substrate 00 is located may be different. This embodiment where the orthographic projection of the first floating metal portion 21 on the plane where the substrate 00 is located is a trapezoid and the orthographic projection of the second floating metal portion 22 on the plane where the substrate 00 is located is a rectangle is used as an example to illustrate the present disclosure. At this time, the width of the first floating metal portion 21 along the second direction D2 may be not fixed, and the width of the second floating metal portion 22 along the second direction D2 may be fixed, such that the widths of the first floating metal portion 21 and the second floating metal portion 22 along the second direction D2 are different. When the first floating metal portion 21 and the second floating metal portion 22 are arranged in an asymmetric manner, the first floating metal portion 21 and the second floating metal portion 22 may be also in contact with the side walls of the concave structure 109 respectively, and the effect of extracting the heat of the thin film transistor may also be achieved. It should be noted that the planar structure of the first floating metal portion 21 and the second floating metal portion 22 in FIG. 14 is only for illustration. In some other embodiments of the present disclosure, the first floating metal portion 21 and the second floating metal portion 22 may also be respectively set to other asymmetric structures.

As shown in FIG. 14 with reference to FIG. 13, in one embodiment, the extension direction of the edge of the orthographic projection of the first floating metal portion 21 to the substrate 00 close to the concave structure 109 may be not perpendicular to the second direction D2. FIG. 14 shows the relative positional relationship of the film layers in the thin film transistor and the orthographic projection of the first floating metal portion 21 and the second floating metal portion 22 on the substrate 00, and takes the orthographic projection of the first floating metal portion 21 as a trapezoid and the orthographic projection of the second floating metal portion 22 as a rectangle as an example for explanation. In this embodiment, the edge of the orthographic projection of the first floating metal portion 21 on the substrate 00 close to the concave structure 109 may be regarded as the side waist of the trapezoidal structure, and the extension direction of the side waist of the trapezoid may be not perpendicular to the second direction D2. Therefore, the effective contact area between the side wall of the first floating metal portion 21 facing the concave structure 109 and the concave structure 109 may be increased, which is beneficial to improving the heat dissipation efficiency of the thin film transistor.

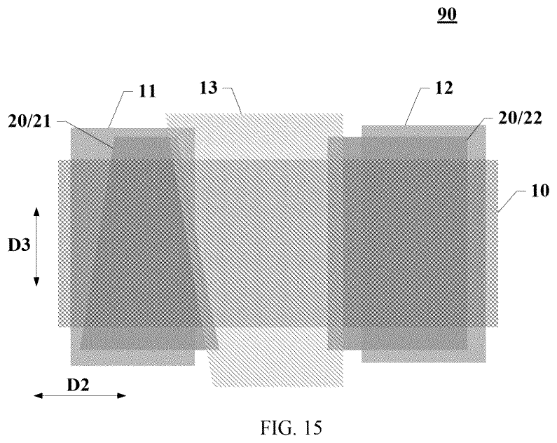

In the direction perpendicular to the substrate, the gate 13 may cover the edge of the first floating metal portion 21 and the second floating metal portion 22 close to the concave structure. Optionally, when the edge of the first floating metal portion 21 close to the concave structure is an inclined edge, the edge of the orthographic projection of the gate 13 adjacent to the edge of the first floating metal portion 21 close to the concave structure in the plane where the substrate is located may also be an inclined edge, and the two edges may be in a parallel relationship, such that the two edges are more spatially adapted, for example, please refer to FIG. 15 which is another planar structure diagram of a thin film transistor in the display panel provided by the present disclosure.

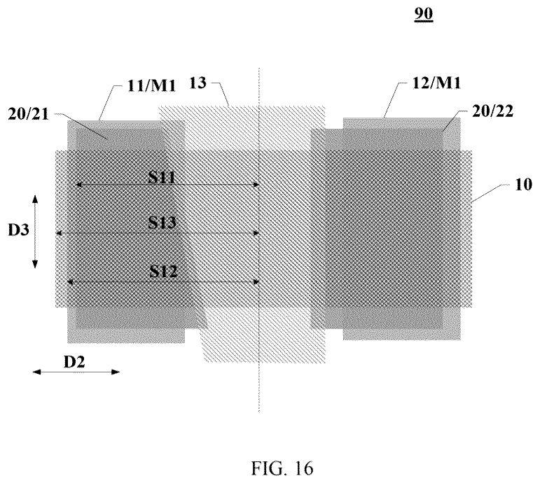

FIG. 14 and FIG. 15 are only used as examples in which the orthographic projection of the first floating metal portion 21 on the substrate 00 is an isosceles trapezoid, to illustrate the present disclosure, and do not limit the scope of the present disclosure. In some other embodiments of the present disclosure, the orthographic projection of the first floating metal portion 21 on the substrate 00 may also be a right-angled trapezoid, whose inclined side corresponds to the edge of the first floating metal portion 21 facing the concave structure 109, for example, as shown in FIG. 16, which is also beneficial to increasing the effective contact area between the first floating metal portion 21 and the active layer 10. FIG. 16 shows another planar structure diagram of a thin film transistor in the display panel provided by the present disclosure.

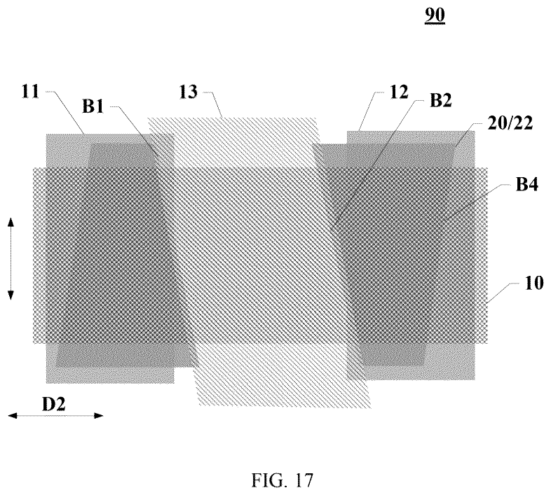

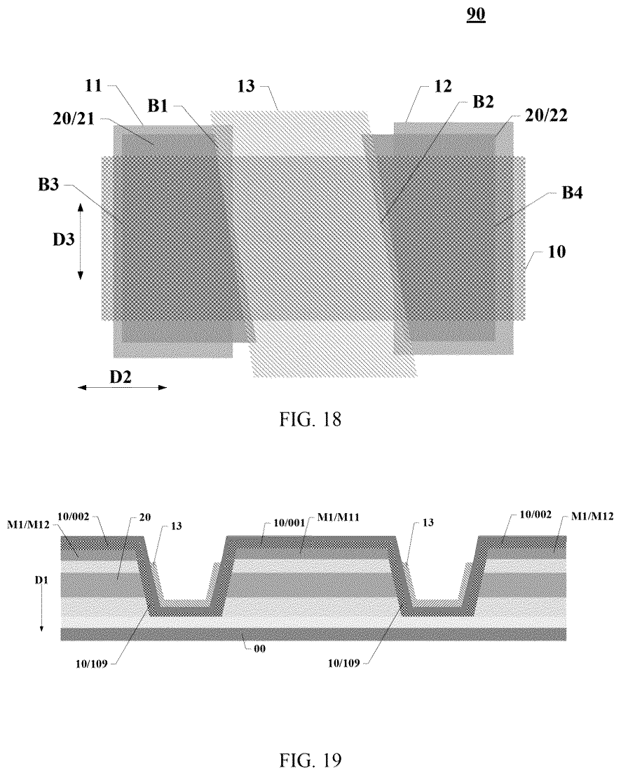

In another embodiment shown in FIG. 17 and FIG. 18 which are another planar structure diagram of a thin film transistor in the display panel provided by the present disclosure, the edge of the orthographic projection of the first floating metal portion 21 close to the concave structure 109 in the substrate 00 may be the first edge B1; the edge of the orthographic projection of the second floating metal portion 22 close to the concave structure 109 in the substrate 00 may be the second edge B2; and the first edge B1 and the second edge B2 may be parallel.

In the embodiments shown in FIG. 17 and FIG. 18 respectively illustrating another structure in which the first floating metal portion 21 and the second floating metal portion 22 are asymmetrically arranged, the edge of the orthographic projection of the first floating metal portion 21 close to the concave structure 109 in the substrate 00 may be the first edge B1, and the extension direction of the first edge B1 may be not perpendicular to the second direction D2. The edge of the orthographic projection of the second floating metal portion 22 close to the concave structure 109 in the substrate 00 may be the second edge B2, and the extension direction of the second edge B2 may also not be perpendicular to the second direction D2. This may be equivalent to setting the side wall of the first floating metal portion 21 facing the concave structure 109 and the side wall of the second floating metal portion 22 facing the concave structure 109 to be inclined structures, which may simultaneously increase the actual contact area between the side wall of the first floating metal portion 21 and the active layer 10, and the actual contact area between the side wall of the second floating metal portion 22 and the active layer 10, thereby facilitating the improvement of the heat dissipation capacity of the thin film transistor. Further, in this embodiment, the first edge B1 corresponding to the first floating metal portion 21 and the second edge B2 corresponding to the second floating metal portion 22 may be set to be parallel. In actual manufacturing, the plane where the side wall of the first floating metal portion 21 facing the concave structure 109 is located and the plane where the side wall of the second floating metal portion 22 facing the concave structure 109 is located may be set to be parallel, which is also conducive to simplifying the manufacturing process of the first floating metal portion 21 and the second floating metal portion 22.

Along the direction perpendicular to the substrate, the gate 13 may not only cover the first edge B1 and the second edge B2, but also the two edges of the gate 13 opposite to each other along the second direction D2 may be respectively parallel to the first edge B1 and the second edge B2, such that the gate 13 and the floating metal layer 20 are more spatially adapted.

Optionally, the orthographic projection of the first floating metal portion 21 in the plane where the substrate 00 is located, may also include a third edge B3 arranged opposite to the first edge B1 along the second direction D2, and the third edge B3 may be regarded as the edge of the first floating metal portion 21 away from the concave structure 109. The orthographic projection of the second floating metal portion 22 in the plane where the substrate 00 is located, may also include a fourth edge B4 arranged opposite to the second edge B2 along the second direction D2, and the fourth edge B4 may be regarded as the edge of the second floating metal portion 22 away from the concave structure 109. It should be noted that, when the first edge B1 corresponding to the first floating metal portion 21 and the second edge B2 corresponding to the second floating metal portion 22 are set to be parallel, the third edge B3 corresponding to the first floating metal portion 21 and the fourth edge B4 corresponding to the second floating metal portion 22 may be set to a non-parallel structure as shown in FIG. 17, or may be set to a parallel structure as shown in FIG. 18. Taking FIG. 17 as an example, in one embodiment, the orthographic projections of the first floating metal portion 21 and the second floating metal portion 22 on the substrate 00 may both be embodied as isosceles trapezoids. Taking FIG. 18 as an example, in another embodiment, the orthographic projections of the first floating metal portion 21 and the second floating metal portion 22 may both be embodied as right-angled trapezoids. In the embodiments shown in FIG. 17 and FIG. 18, one of the isosceles trapezoids may be equivalent to the other isosceles trapezoids obtained by rotating 180 degrees on the plane where the substrate 00 is located. Of course, when the first edge B1 and the second edge B2 are parallel, the third edge B3 and the fourth edge B4 may also be embodied as other structures other than FIG. 17 and FIG. 18, and the present disclosure does not specifically limit this.

In one embodiment shown in FIG. 3 to FIG. 6, or shown in FIG. 12 and FIG. 13, in one embodiment, the active layer 10 may also include an extension 103 connected to the side surface 102 of the concave structure 109, and the extension 103 may be located on the side of the floating metal layer 20 away from the substrate 00. The display panel may further include a first metal layer M1, and the first metal layer M1 may be located on the side of the floating metal layer 20 away from the substrate 00 and in contact with the extension 103. At least one of the source or drain of the thin film transistor may be located in the first metal layer M1.

When the thin film transistor is embodied as an annular structure as shown in FIG. 3 to FIG. 6, or a non-annular structure as shown in FIG. 12 and FIG. 13, the first metal layer M1 may be disposed on the side of the floating metal layer 20 away from the substrate 00, and the first metal layer M1 may be embodied as a ring structure as shown in FIG. 3. At this time, one of the source or drain in the thin film transistor may be disposed in the first metal layer M1. The first metal layer M1 may also be embodied as two independent block structures as shown in FIG. 12 and FIG. 13, which serve as the source and drain of the thin film transistor respectively. In the present embodiment, along the first direction D1, the first metal layer M1 may be located between the floating metal layer 20 and the extension 103 of the active layer 10, and the surface of the first metal layer M1 facing away from the substrate 00 may be in direct contact with the extension of the active layer 10, which is beneficial to increase the contact area between the first metal layer M1 and the active layer 10. The surface of the first metal layer M1 facing the substrate 00 may be isolated from the floating metal layer 20 by an insulating layer to avoid a short circuit between the first metal layer M1 and the floating metal layer 20.

In one embodiment, as shown in FIG. 6, the angle between the surface facing the substrate 00 and the side wall facing the center line of the concave structure 109 of the first metal layer M1 may be θ, where 60°≤θ≤80°. When the first metal layer M1 is arranged on the side of the extension 103 of the active layer 10 facing the substrate 00 and in direct contact with the extension 103 of the active layer 10, in the actual process, the active layer 10 may be deposited after the first metal layer M1 is formed. Therefore, in the process of depositing the active layer 10, the active layer 10 may not only adhere to the surface of the first metal layer M1 away from the substrate 00, but also adhere to the side wall of the first metal layer M1 facing the groove 21. The thickness of the first metal layer M1 may affect the electrical properties of the source and drain 11 of the thin film transistor. When the first metal layer M1 is too thin, the electrical connection reliability of the thin film transistor may be reduced. When the above-mentioned angle θ is too small, for example, less than 60°, the first metal layer M1 may be bound to have a relatively thin area in a large range, which affects the electrical performance reliability as the source or drain of the thin film transistor. When the angle θ is too large, for example, greater than 80°, the slope of the side wall of the first metal layer M1 may be steep, which is not conducive to the adhesion of the subsequently deposited active layer 10. Therefore, the present embodiment may set the angle between the side wall in the first metal layer M1 that contacts the active layer 10 and the surface of the first metal layer M1 facing the substrate 00 to 60°≤θ≤80°, which may meet the thickness requirements of the thin film transistor for the first metal layer M1 and improve the reliability of the electrical performance of the source and drain 11 of the thin film transistor. At the same time, the angle may be set to be less than or equal to 80°, and the slope of the side wall of the first metal layer M1 may be gentle, which is conducive to the adhesion of the active layer 10 to the side wall of the first metal layer M1 and improves the coverage reliability of the active layer 10 on the side wall of the first metal layer M1. Optionally, 65°≤θ≤75°, or 70°≤θ≤78°, etc.

In one embodiment shown in FIG. 6, the first metal layer M1 and the floating metal layer 20 may be isolated by the first insulating layer 31. The angle between the surface of the first insulating layer 31 facing the substrate 00 and the side wall facing the center line X of the concave structure 109 may be β, and 60°≤β≤80°.

To avoid short circuit between the first metal layer M1 and the floating metal layer 20, the first insulating layer 31 may be disposed between the first metal layer M1 and the floating metal layer 20 to isolate the first metal layer M1 and the floating metal layer 20. In the actual process, after the first insulating layer 31 and the first metal part M11 are formed, the active layer 10 may be deposited. Therefore, during the deposition of the active layer 10, the active layer 10 may contact the side surface 102 of the first insulating layer 31 facing the concave structure 109. When the angle β between the surface of the first insulating layer 31 facing the substrate 00 and the side wall facing the center line X of the concave structure 109 is set to be too small, for example, less than 60°, the thickness of the first insulating layer 31 may be thin, and the corresponding insulation effect cannot be achieved. When the angle β is greater than 80°, the slope of the side wall of the first insulating layer 31 may be steep, which is not conducive to the adhesion of the subsequently deposited active layer 10, and may affect the reliability of the thin film transistor. Therefore, the present embodiment may set the angle between the side wall of the first insulating layer 31 facing the concave structure 109 and the surface facing the substrate 00 to 60°≤β≤80°, which may not only keep the first insulating layer 31 at a certain thickness to ensure the insulation reliability between the first metal layer M1 and the floating metal layer 20, but also facilitate the adhesion of the active layer 10 to the side wall of the first insulating layer 31, thereby facilitating the coverage reliability of the active layer 10 on the side wall of the first insulating layer 31. Optionally, 65°≤β≤75°, or 70°≤β≤78°, etc.

In one embodiment shown in FIG. 6, the side surface 102 of the floating metal layer 20 facing the concave structure 109, the side surface 102 of the first insulating layer 31 facing the concave structure 109, and the side surface 102 of the first metal layer M1 facing the concave structure 109 may all be set to be inclined structures, and the inclination angles α, β and θ of the three may be set to be the same.

In one embodiment shown in FIG. 6, the first metal layer M1 and the floating metal layer 20 may be isolated by the first insulating layer 31. The end of the first metal layer M1 toward the concave structure 109, the end of the first insulating layer 31 toward the concave structure 109, and the end of the floating metal layer 20 toward the concave structure 109 may form a step structure. Along the direction from the bottom surface 101 of the concave structure 109 to the mouth, the inner diameter of the concave structure 109 may tend to increase.

In this embodiment, the end of the first metal layer M1 facing the concave structure 109, the end of the first insulating layer 31 facing the concave structure 109 and the end of the floating metal layer 20 facing the concave structure 109 may form a step structure. That is, at least part of the surface of the floating metal layer 20 facing away from the substrate 00 may not be covered by the first insulating layer 31 and the surface of the floating metal layer 20 not covered by the first insulating layer 31 may be arranged close to the concave structure 109; at least part of the surface of the first insulating layer 31 facing away from the substrate 00 may not be covered by the first metal layer M1 and the surface of the first insulating layer 31 not covered by the first metal layer M1 may be arranged close to the concave structure 109. Thus, when depositing the active layer 10, after the active layer 10 climbs the side wall of the floating metal layer 20, the active layer 10 may first pass through a gentle space on the upper surface of the floating metal layer 20, and then climb the side wall of the first insulating layer 31. That is to say, there may be a section of the active layer 10 arranged parallel to the substrate 00 for buffering between each inclined active layer 10, which is more conducive to improving the adhesion reliability of the active layer 10, thereby improving the stability of the thin film transistor.

It should be noted that, as shown in FIG. 6, when another insulating layer (assuming that it is a second insulating layer 32) is arranged on the side of the floating metal layer 20 facing the substrate 00, at least part of the surface of the second insulating layer 32 facing away from the substrate 00 may not be covered by the floating metal layer 20, and a step structure may be also formed. The inclination of the side wall of the second insulating layer 32 toward the concave structure 109 may be set to be the same as that of the floating metal layer 20, to further improve the adhesion reliability of the active layer 10.

In another embodiment shown in FIG. 4 and FIG. 6, the gate 13 may not overlap with the first metal layer M1 along the radial direction of the concave structure 109.

Considering that the first metal layer M1 is used to set the source and/or drain of the thin film transistor, when the gate 13 of the thin film transistor overlaps with the source or drain, a parasitic capacitance may be generated between the gate 13 and the source or drain. When the parasitic capacitance is large, it may affect the normal opening or closing of the channel region by the gate 13. Therefore, the present embodiment may set the gate 13 and the first metal layer M1 not to overlap along the radial direction of the concave structure 109, which is conducive to avoiding the formation of lateral parasitic capacitance between the side of the first metal layer M1 and the gate 13.

In another embodiment shown in FIG. 4 and FIG. 6, the end surface of the gate 13 away from the substrate 00 may be located in the same plane as the surface of the first metal layer M1 facing the substrate 00.

In existing technologies, the area occupied by the thin film transistor in the display panel is reduced by reducing the length of the channel region of the thin film transistor, thereby improving the PPI of the display panel. However, when the length of the channel region is too small, it will cause excessive accumulation of electrons in the channel region, causing the thin film transistor to heat up or burn. The present disclosure may set the gate 13 at least on one side of the concave structure of the active layer 10, which is equivalent to forming an inclined channel structure. Compared with the channel of the horizontal structure, in the same unit area space, the length of the inclined channel region may be set to be greater than the length of the horizontal channel region, thereby avoiding the self-heating problem caused by the short length of the channel region. Further, the present disclosure may set the active layer 10 to include the concave structure 109, which may also reduce the area occupied by the thin film transistor in the display panel and improve the PPI of the display panel. In this embodiment, the end surface of the gate 13 away from the substrate 00 may be arranged in the same plane as the surface of the first metal layer M1 facing the substrate 00. The length of the channel region may be increased by extending the gate 13 in the direction away from the substrate 00. At the same time, the overlap between the gate 13 and the first metal layer M1 along the radial direction of the concave structure 109 may be avoided, thereby avoiding the generation of lateral parasitic capacitance between the gate 13 and the source and drain 11 of the thin film transistor.

In one embodiment shown in FIG. 13 and FIG. 16, along the radial direction of the concave structure 109, the distance S11 between the end of the floating metal layer 20 away from the center line of the concave structure 109 and the center line of the concave structure 109 may be smaller than the distance S12 between the end of the first metal layer M1 away from the center line of the concave structure 109 and the center line of the concave structure 109. This arrangement may be equivalent to that the outer edge of the first metal layer M1 away from the center line of the concave structure 109 exceeds the outer edge of the floating metal layer 20 away from the center line of the concave structure 109. In this way, while ensuring the heat dissipation effect of the floating metal layer 20, it may be also beneficial to reduce the overlapping area of the floating metal layer 20 and the first metal layer M1, thereby reducing the coupling capacitance that may be generated between the floating metal layer 20 and the first metal layer M1.

In one embodiment shown in FIG. 13 and FIG. 16, along the radial direction of the concave structure 109, the distance S13 between the end of the active layer 10 away from the center line of the concave structure 109 and the center line of the concave structure 109 may be greater than the distance S12 between the end of the first metal layer M1 away from the center line of the concave structure 109 and the center line of the concave structure 109. That may be equivalent to that the outer edge of the active layer 10 away from the center line of the concave structure 109 exceeds the outer edge of the first metal layer M1 away from the center line of the concave structure 109, which is conducive to increasing the contact area between the first metal layer M1 and the active layer 10, thereby facilitating increasing the contact area between the source or drain located on the first metal layer M1 and the active layer 10, and facilitating improving the performance stability of the thin film transistor.

In one embodiment shown in FIG. 4 and FIG. 6, the display panel may further include a second metal layer M2 which is located on the side of the bottom surface 101 of the concave structure 109 facing the substrate 00 and in contact with the bottom surface 101 of the concave structure 109. One of the source or the drain in the thin film transistor may be located on the first metal layer M1, and the other may be located on the second metal layer M2.

In this embodiment, the second metal layer M2 may be introduced in the display panel, and the second metal layer M2 may be located between the substrate 00 and the bottom surface 101 of the concave structure 109. In the actual manufacturing process, after the second metal layer M2 is formed on one side of the substrate 00, the floating metal layer 20 and the first metal layer M1 may be formed on the side of the second metal layer M2 away from the substrate 00. The floating metal layer 20 and the second metal layer M2, and the floating metal layer 20 and the first metal layer M1 may be isolated by an insulating layer, and the active layer 10 may be deposited after these film layers are formed. The first metal layer M1 and the second metal layer M2 may be in direct contact with the active layer 10. The source of the thin film transistor may be located in the first metal layer M1 or the second metal layer M2. Correspondingly, the drain of the thin film transistor may be located in the second metal layer M2 or the first metal layer M1. At this time, the second metal layer M2 may be embodied as a strip structure, and the first metal layer M1 may be embodied as a ring structure. That is to say, the first metal layer M1 on two sides of the concave structure 109 may be actually electrically connected. This solution is particularly suitable for the thin film transistor with a ring structure. The gate 13 may be arranged on the inner side of the concave structure 109 to form an inclined channel region. While ensuring the length of the channel region, it may be also beneficial to reduce the area occupied by the thin film transistor in the display panel, so it is beneficial to improve the PPI of the display panel.

In one embodiment shown in FIG. 4 and FIG. 6, along the first direction D1, the gate 13 may not overlap at least partially with the bottom surface 101 of the concave structure 109.

When the first metal layer M1 and the second metal layer M2 are respectively introduced into the display panel to set the source or drain of the thin film transistor, along the first direction D1, the first metal layer M1 and the second metal layer M2 may be located on different sides of the floating metal layer 20. When the gate 13 extends laterally in the concave structure 109, the longer the extension length is, the greater the corresponding channel length is, which is more conducive to avoiding the self-heating effect of the thin film transistor caused by the too short channel. However, the gate 13 may form a coupling capacitor with other metal layers when extending. Therefore, the end of the gate 13 away from the substrate 00 may only extend below the first metal layer M1 or maybe flush with the surface of the first metal layer M1 facing the substrate 00, avoiding the formation of lateral parasitic capacitance between the gate 13 and the first metal layer M1. The end of the gate 13 facing the substrate 00 may only extend to the bottom of the side 102 of the concave structure 109, and may not extend further on the bottom surface 101 of the concave structure 109. That is to say, along the first direction D1, the gate 13 and the bottom surface 101 of the concave structure 109 may at least partially not overlap, which may reduce the coupling capacitance between the gate 13 and the second metal layer M2, thereby ensuring the performance stability of the thin film transistor.

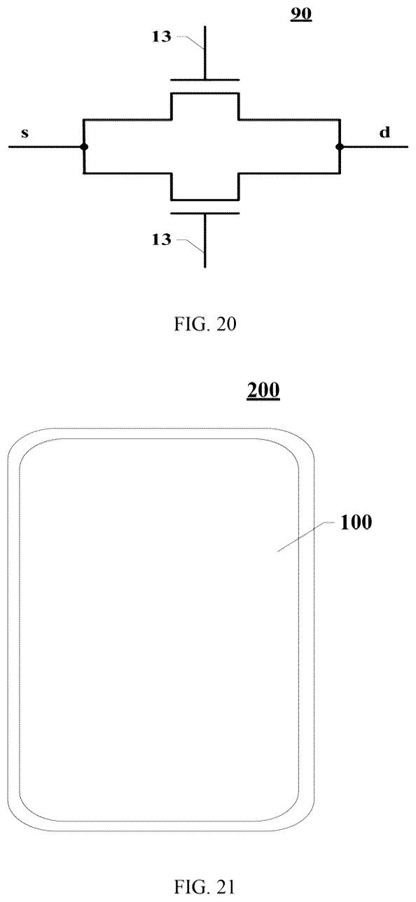

As shown in FIG. 19 which is another film layer structure of the thin film transistor and FIG. 20 which is an electronic device diagram corresponding to the thin film transistor shown in FIG. 19, in one embodiment, the extension between two adjacent concave structures 109 may be connected to form an intermediate extension 001, and the extension extending to the periphery of the two adjacent concave structures 109 may form an edge extension 002. The first metal layer M1 may include a first metal portion M11 and a second metal portion M12. The first metal portion M11 may be in contact with the intermediate extension 001, and the second metal portion M12 may be in contact with the edge extension 002. The first metal portion M11 may be used as one of the source or the drain of the thin film transistor, and the second metal portion M12 may be used as the other of the source and the drain of the thin film transistor.

In this embodiment, the thin film transistor may be a dual-gate structure thin film transistor. The thin film transistor may include two gates 13, and the active layer 10 of the same thin film transistor may include two concave structures 109. The two gates 13 may be respectively located inside the two concave structures 109. The source and drain of the thin film transistor may be both located in the first metal layer M1. The first metal layer M1 may include the first metal portion M11 in contact with the intermediate extension 001 of the active layer 10 and the second metal portion M12 in contact with the edge extension 002 of the active layer 10. The first metal portion M11 may serve as the source of the thin film transistor, and the second metal portion M12 may serve as the drain of the thin film transistor. Or, the first metal portion M11 may serve as the drain of the thin film transistor, and the second metal portion M12 may serve as the source of the thin film transistor. For a dual-gate thin film transistor, the active layer 10 may include two concave structures 109. Compared with the planar active layer 10, it may be also beneficial to reduce the area occupied by the dual-gate thin film transistor in the display panel, thereby improving the PPI of the display panel. At the same time, it may be also beneficial to ensure the length of the channel region to avoid self-heating caused by a short channel. In addition, for a dual-gate thin film transistor, it may provide a larger current, and some transistors in the display panel may be set to a dual-gate structure as shown in FIG. 19 or FIG. 20 according to actual needs.

In one embodiment shown in FIG. 19, the orthographic projection of the second metal portion M12 on the substrate 00 may at least partially surround the two adjacent concave structures 109.

In this embodiment, the second metal portion M12 may contact the edge extension in the active layer 10 to form a source or drain of the thin film transistor with a dual-gate structure. The edge extension and the second metal portion M12 may be located at the periphery of the two concave structures 109 corresponding to the thin film transistor with a dual-gate structure. Since the second metal portion M12 constitutes one of the source or drain in the thin film transistor, the second metal portion M12 located at the periphery of the two concave structures 109 may need to form an electrical connection. To simplify the manufacturing process of the thin film transistor, the second metal portion M12 may be set as a ring structure arranged around the two concave structures 109, such that the thin film transistor with a dual-gate structure presents a ring structure, which is also conducive to improving the PPI of the display panel and avoiding the self-heating problem of the thin film transistor due to the short channel length.

In one embodiment shown in FIG. 19, along the first direction D1, the gate 13 may overlap with the bottom surface 101 of the concave structure 109, and the portion of the gate 13 overlapping with the side of the concave structure 109 and the portion overlapping with the bottom surface of the concave structure 109 may be connected to each other.

Compared with the embodiment shown in FIG. 4, in the thin film transistor provided by the embodiment shown in FIG. 19, the source and the drain may both be disposed in the first metal layer M1, and may be both located on the side of the floating metal layer 20 away from the substrate 00, No metal layer may be provided on the side of the gate 13 facing the substrate 00, such that the gate 13 of the thin film transistor may extend to the top of the bottom surface 101 of the concave structure 109, which is conducive to increasing the length of the channel region of the thin film transistor and further avoiding the self-heating problem caused by the short channel.

In an optional embodiment of the present disclosure, the floating metal layer 20 may be floating. That is, the floating metal layer 20 may be not connected to any signal, may not transmit signals, and may be only used for heat conduction, which is conducive to avoiding the problem of unstable signals of thin film transistors caused by connecting signals to the floating metal layer 20.

Optionally, the material of the floating metal layer 20 can be selected to be the same as the material of the first metal layer M1, such that there is no need to introduce new materials in the display panel, which is conducive to saving production costs. In one embodiment, the floating metal layer 20 may be made of materials including Mo or Cu.

In an optional embodiment of the present disclosure, the active layer 10 may include a metal oxide, such that the corresponding transistor is embodied as an oxide transistor. The oxide transistor in the display panel may be set using the structure provided by the present disclosure to reduce the area occupied by the oxide thin film transistor in the display panel and improve the PPI of the display panel. Metal oxides may include, for example, IGZO (indium gallium zinc oxide), etc., which is not specifically limited in the present disclosure.

In the actual structure of the display panel, the pixel driving circuit is connected to the sub-pixel to drive the sub-pixel to emit light. The pixel driving circuit can be embodied as 2T1C (representing two transistors and one capacitor), 7T1C (representing seven transistors and one capacitor), etc. For the specific structure of the pixel driving circuit, reference may be made to the relevant technology, and the present disclosure will not be specifically limited. The pixel driving circuit usually includes a driving transistor, which is used to generate a driving current for driving the sub-pixel to emit light. The driving transistor is prone to self-heating. Therefore, the driving transistor in the pixel driving circuit may be set using the structure of the thin film transistor of the present disclosure, which is beneficial to reducing the area occupied by the driving transistor in the display panel, and can also timely remove the heat generated in the channel region of the driving transistor through the floating metal layer, thereby helping to avoid the problem of self-heating of the driving transistor. The potential of the gate of the driving transistor will directly affect the accuracy of the driving current generated by the driving transistor. When the gate of the driving transistor is connected to other transistors, the thin film transistor connected to it may generate a coupling capacitance during the switching process to affect the potential of the gate of the driving transistor. Therefore, the transistor connected to the gate of the driving transistor may be set to the structure of the transistor provided by the present disclosure, and the material of the active layer may be set to metal oxide, such that the transistor connected to the gate of the driving transistor is embodied as a metal oxide transistor to reduce the leakage problem of this part of the transistor to the thin film transistor, improve the stability of the gate potential of the driving transistor, and also help to improve the PPI of the display panel.

In some other embodiments of the present disclosure, each transistor in the pixel driving circuit may be set to a structure corresponding to the present disclosure, which is beneficial to reducing the area occupied by the pixel driving circuit in the display panel. One or more of the transistors in other circuits may also be set to a structure corresponding to the present disclosure, which is more beneficial to improving the PPI of the display panel.

The present disclosure also provides a display device. As shown in FIG. 21 which is a display device provided by the present disclosure, the display device may include a display panel 100 provided by various embodiments of the present disclosure. The display device may also have benefits of the display panel 100 provided by various embodiments of the present disclosure, and for the details, references may be made to the above description about the display panel 10.

In one embodiment, the display device 200 may any electronic product with display function or touch function, including but not limited to, a cell phone, a television, a laptop computer, a desktop computer, a tablet, a digital camera, a smart bracelet, smart glasses, a vehicle display, an industrial control device, a medical display panel, a touch interaction terminal, and so on. The present disclosure has no limit on this.

In the display panel and display device provided by the present disclosure, the active layer of the thin film transistor may include the concave structure formed along the first direction, rather than a planar structure in an existing TFT device. When the length of the active layer is constant, the projection area of the projection of the active layer on the plane where the light-emitting surface of the display panel is located may be smaller when the active layer is set to the concave structure than when the active layer is set to the planar structure, which is more conducive to reducing the area occupied by the thin film transistor in the display panel, and is conducive to improving the PPI of the product. When the active layer is set to include the concave structure in the present disclosure, at least part of the channel region may be located on one side of the side of the concave structure that intersects with the bottom surface of the concave structure, and the length of the channel region may be also related to the length of the side of the concave structure. That is to say, the present disclosure may be conducive to increasing the length of the channel region when the thin film transistor is set in a smaller area. Even when the area occupied by the thin film transistor in the display panel is reduced to improve the PPI, the length of the channel region may be still ensured to be not too short, thereby avoiding the problem of heating or burning caused by excessive accumulation of electrons in the channel.

Also, in the present disclosure, the floating metal layer may be disposed in the display panel, and the floating metal layer may be in direct contact with the side of at least part of the concave structure in the thin film transistor. On the one hand, the channel region of the active layer may be in direct contact with the floating metal layer, which effectively reduces the source-drain voltage difference of the thin film transistor, improves the negative bias of the threshold voltage of the thin film transistor, and improves the display quality. On the second hand, the active layer may be in direct contact with the floating metal layer, and when the thin film transistor generates heat, the heat may be conducted to the floating metal layer through the concave structure, and the floating metal layer may be able to conduct the heat to avoid heat accumulation in the channel region which cause the thin film transistor to heat up or burn. The stability of the performance of the thin film transistor may be improved. On the third hand, the floating metal layer may be in direct contact with the side of at least part of the concave structure in the channel region of the active layer. The floating metal layer contacting with the side of the concave structure may realize the adjustment of the contact area between the floating metal layer and the concave structure by adjusting the angle of the side of the floating metal layer, and at the same time, it may ensure that the length of the channel region is kept within a reasonable range.

In the present disclosure, relational terms such as “first” and “second” are only used to distinguish one entity or operation from another entity or operation, and do not necessarily require or imply that there is a relationship between these entities or operations. There is no such actual relationship or sequence. Furthermore, the terms “comprises”, “include”, or any other variations thereof are intended to cover a non-exclusive inclusion such that a process, method, article, or apparatus that includes a list of elements includes not only those elements, but also those not expressly listed, or elements inherent to the process, method, article or equipment. Without further limitation, an element defined by the statement “comprises a . . . ” does not exclude the presence of additional identical elements in a process, method, article, or apparatus that includes the stated element.

Various embodiments have been described to illustrate the operation principles and exemplary implementations. It should be understood by those skilled in the art that the present disclosure is not limited to the specific embodiments described herein and that various other obvious changes, rearrangements, and substitutions will occur to those skilled in the art without departing from the scope of the disclosure. Thus, while the present disclosure has been described in detail with reference to the above described embodiments, the present disclosure is not limited to the above described embodiments, but may be embodied in other equivalent forms without departing from the scope of the present disclosure, which is determined by the appended claims.

What is claimed is:

1. A display panel, comprising a substrate and an array layer on a side of the substrate, wherein:
the array layer includes at least one thin film transistor;
one thin film transistor of the at least one thin film transistor includes an active layer, a gate, a source, and a drain;
the active layer is located on one side of the substrate;
the active layer includes a concave structure formed along a first direction, and the concave structure includes a bottom surface of the concave structure and a side surface of the concave structure;
the gate is located on a side of the active layer away from the substrate, wherein: along a direction perpendicular to the plane where the side surface of the concave structure is located, at least part of the gate overlaps with the side surface of the concave structure;
the array layer includes a floating metal layer, and the floating metal layer is located between the active layer and the substrate, wherein the floating metal layer is in direct contact with at least part of the side surface of the concave structure; and
the first direction is perpendicular to the substrate and is from the floating metal layer to the substrate.

2. The display panel according to claim 1, wherein:
the side surface of the concave structure includes a first region;
along the direction perpendicular to the plane where the side surface of the concave structure is located, the gate overlaps with the first region, and the floating metal layer directly contacts at least a portion of the first region.

3. The display panel according to claim 1, wherein:
a surface of the floating metal layer away from the substrate is a first surface; and
a side surface of the floating metal layer facing the concave structure and at least a portion of the first surface are in contact with the side surface of the concave structure.

4. The display panel according to claim 3, wherein:
along an extension direction of the active layer, a contact width between the active layer and the first surface of the floating metal layer located on the side of the concave structure is S1, a contact width between the active layer and the side wall of the floating metal layer located on the side of the concave structure is S0, and a sum of contact widths between the active layer and the first surface of the floating metal layer located on two sides of the concave structure is S2, wherein S1<S0, and S0/2<S2.

5. The display panel according to claim 3, wherein:
a sidewall of the floating metal layer facing the concave structure includes grooves; or
the first surface of the floating metal layer in contact with the active layer includes grooves.

6. The display panel according to claim 1, wherein:
a surface of the floating metal layer facing the substrate is a second surface, and an angle between the sidewall of the floating metal layer facing the concave structure and the second surface is a, wherein 60°≤α≤80°.

7. The display panel according to claim 1, wherein:
along the first direction, a thickness of the floating metal layer is H0;
an area where the gate and the active layer overlap is a channel region of the thin film transistor, and a length of the channel region on a single side of the concave structure is L, wherein a length direction of the channel region is from the bottom surface of the concave structure to a mouth of the concave structure on the side of the concave structure; and
L/3≤H0≤L/2.

8. The display panel according to claim 1, wherein:
the floating metal layer includes a first floating metal portion and a second floating metal portion which are arranged opposite to each other along a second direction;
the first floating metal portion and the second floating metal portion are respectively in contact with two opposite side surfaces of the same concave structure; and
the second direction is parallel to the plane where the substrate is located and parallel to the extension direction of the active layer on the bottom surface of the concave structure.

9. The display panel according to claim 1, wherein:
along a third direction, a width of the gate is S1, a width of the floating metal layer is S2, and a width of the active layer is S3, wherein: S1>S2>S3, and the third direction is parallel to a light emitting surface of the display panel and perpendicular to the second direction.

10. The display panel according to claim 8, wherein:
a width of the first floating metal portion along the second direction is different from a width of the second floating metal portion along the second direction; and
in an orthographic projection of the first floating metal portion to the substrate, an extension direction of an edge close to the concave structure is not perpendicular to the second direction.

11. The display panel according to claim 10, wherein:
an edge of the orthographic projection of the first floating metal portion on the substrate close to the concave structure is a first edge, and an edge of an orthographic projection of the second floating metal portion on the substrate close to the concave structure is a second edge; wherein the first edge and the second edge are parallel.

12. The display panel according to claim 1, wherein:
the active layer further includes an extension connected to the side of the concave structure, wherein the extension is located on a side of the floating metal layer away from the substrate;
the display panel further includes a first metal layer, wherein: the first metal layer is located on the side of the floating metal layer away from the substrate and in contact with the extension, and at least one of the source or the drain of the thin film transistor is located in the first metal layer; and
an angle between the surface of the first metal layer facing the substrate and a side wall facing the center line of the concave structure is θ, wherein 60°≤θ≤80°.

13. The display panel according to claim 12, wherein:
the first metal layer and the floating metal layer are isolated by a first insulating layer, and an angle between a surface of the first insulating layer facing the substrate and a side wall facing the center line of the concave structure is β, wherein 60°≤β≤80°.

14. The display panel according to claim 12, wherein:
the first metal layer and the floating metal layer are separated by a first insulating layer;
an end of the first metal layer toward the concave structure, an end of the first insulating layer toward the concave structure, and an end of the floating metal layer toward the concave structure form a step structure; and
an inner diameter of the concave structure tends to increase along a direction from the bottom surface to the mouth of the concave structure.

15. The display panel according to claim 12, wherein:
along the radial direction of the concave structure, a distance between the end of the floating metal layer away from the center line of the concave structure and the center line of the concave structure is smaller than the distance between the end of the first metal layer away from the center line of the concave structure and the center line of the concave structure.

16. The display panel according to claim 12, wherein:
along the radial direction of the concave structure, the distance between the end of the active layer away from the center line of the concave structure and the center line of the concave structure is larger than the distance between the end of the first metal layer away from the center line of the concave structure and the center line of the concave structure.

17. The display panel according to claim 12, further including a second metal layer, wherein:
the second metal layer is located on a side of the bottom surface of the concave structure facing the substrate and in contact with the bottom surface of the concave structure; and
one of the source or the drain in the thin film transistor is located in the first metal layer, and the other is located in the second metal layer.

18. The display panel according to claim 12, wherein:
extensions between two adjacent concave structures are connected to form an intermediate extension, and the extension extending to a periphery of the two adjacent concave structures is an edge extension;
the first metal layer includes a first metal portion and a second metal portion;
the first metal portion is in contact with the intermediate extension, and the second metal portion is in contact with the edge extension;
the first metal portion serves as one of the source or the drain of the thin film transistor, and the second metal portion serves as the other of the source or the drain of the thin film transistor.

19. The display panel according to claim 18, wherein:
an orthographic projection of the second metal portion on the substrate at least partially surrounds the two adjacent concave structures; or
along the first direction, the gate overlaps with the bottom surface of the concave structure, and a portion of the gate overlapping with the side surface of the concave structure and a portion of the gate overlapping with the bottom surface of the concave structure are connected to each other.

20. A display device comprising a display panel, wherein:
the display panel includes a substrate and an array layer on a side of the substrate;
the array layer includes at least one thin film transistor;
one thin film transistor of the at least one thin film transistor includes an active layer, a gate, a source, and a drain;
the active layer is located on one side of the substrate;
the active layer includes a concave structure formed along a first direction, and the concave structure includes a bottom surface of the concave structure and a side surface of the concave structure;
the gate is located on a side of the active layer away from the substrate, wherein: along a direction perpendicular to the plane where the side surface of the concave structure is located, at least part of the gate overlaps with the side surface of the concave structure;
the array layer includes a floating metal layer, and the floating metal layer is located between the active layer and the substrate, wherein the floating metal layer is in direct contact with at least part of the side surface of the concave structure; and
the first direction is perpendicular to the substrate and is from the floating metal layer to the substrate.
